(19) United States
(12) Patent Application Publication
(10) Pub. No.: US 2024/0158910 A1
(43) Pub. Date: May 16, 2024

(54) MICROWAVE PLASMA CHEMICAL VAPOR DEPOSITION DEVICE

(71) Applicant: Wuhan Youmeike Automation Co., Ltd, Wuhan (CN)

(72) Inventors: Zhiwen KANG, Wuhan (CN); Bingfeng CAI, Wuhan (CN); Kangfu GUO, Wuhan (CN)

(73) Assignee: Wuhan Youmeike Automation Co., Ltd, Wuhan (CN)

(21) Appl. No.: 18/109,873

(22) Filed: Feb. 15, 2023

Related U.S. Application Data
(63) Continuation of application No. PCT/CN2022/139305, filed on Dec. 15, 2022.

(30) Foreign Application Priority Data
Nov. 16, 2022 (CN) 202211436035.0

(51) Int. Cl. C23C 16/27; C23C 16/511; H01J 37/32

(52) U.S. Cl. CPC C23C 16/274; C23C 16/511; H01J 37/32256; H01J 2237/3321

(57) ABSTRACT

A microwave plasma chemical vapor deposition device, including a microwave generator, an isolator, a 3-stub microwave tuner, a microwave mode converter, and a short-circuiting waveguide tuner connected successively is disclosed. A microwave antenna and an upper cooling air inlet stretching into a microwave cavity and corresponding to the upper side of a quartz window are arranged on the microwave mode converter, the quartz window located in the microwave cavity is arranged below the microwave mode converter, a metal molybdenum stage is arranged on a sample stage in the microwave cavity, and a cooling water channel is arranged on the microwave cavity. The structure of the cavity, the sealing structure of the quartz window, heat dissipation and the like of the microwave plasma chemical vapor deposition device disclosed by the present invention are improved, so that the product quality of a diamond film produced by deposition is improved.

### CROSS REFERENCE TO THE RELATED APPLICATIONS

This application is a continuation application of PCT/CN2022/139305, filed Dec. 15, 2022, which is based upon and claims priority to Chinese Patent Application No. 202211436035.0, filed on Nov. 16, 2022, the entire contents of which are incorporated herein by reference.

### TECHNICAL FIELD

The present invention relates to the technical field of diamond synthesis equipment, and particularly to a microwave plasma chemical vapor deposition device.

### BACKGROUND

At present, a frequently used cylindrical resonator is a TM013 resonant mode, using a rounded quartz plate as a quartz window, where plasmas formed are located right below the quartz window. Active ions generated on the plasmas make bombardment on the quartz plate to etch a silicon atom pollution growth atmosphere so as to lead to silicon pollution of the diamond, and a rubber ring for sealing on the quartz window is likely to age and leak air at a high temperature.

A sub-intensive region of a microwave electric field is generated between the quartz window and a plasma region. When the input microwave power is high, the pressure of the cavity is not matched with the input power and secondary plasmas will be generated in the sub-intensive region and the quartz plate is etched, and even the quartz window is burnt out. Therefore, the actual input microwave power of a conventional cylindrical metal resonant cavity type microwave plasma chemical vapor deposition device is lower than 5 KW.

The quartz window not only is a channel to transmit microwaves, but also can isolate the atmospheric barrier. The installation position and structure of the quartz window directly affect its vacuum sealing performance and the silicon pollution caused by plasma bombardment as well as the deposition rate of the diamond film and the quality of a diamond. In order to accelerate the growth rate of the diamond, it has to increase the microwave input power and prevent the microwave window from being etched by the plasmas generated at a high power, thereby preventing silicon impurities etched from polluting the grown diamond.

At present, microwave cavity structures frequently used in the microwave plasma chemical vapor deposition device include a coaxial coupled metal cylindrical cavity structure, a circumferential antenna plasma reactor structure and a coaxial coupled elliptic cavity structure.

### SUMMARY

The objective of the present invention is to provide a microwave plasma chemical vapor deposition device. The structure of the cavity, the sealing structure of the quartz window, heat dissipation and the like are improved, so that the product quality of a diamond film produced by deposition is improved.

In order to achieve the above objective, the present invention provides a microwave plasma chemical vapor deposition device, including a microwave generator, an isolator, a 3-stub microwave tuner, a microwave mode converter and a short-circuiting waveguide tuner connected successively. A microwave antenna and an upper cooling air inlet stretching into a microwave cavity and corresponding to the upper side of a quartz window are arranged on the microwave mode converter, the quartz window located in the microwave cavity is arranged below the microwave mode converter, a metal molybdenum stage is arranged on a sample stage in the microwave cavity, and a cooling water channel is arranged on the microwave cavity.

Preferably, the cooling water channel includes a first cooling water channel arranged below the outer side of the microwave cavity and a second cooling water channel arranged above the outer side of the microwave cavity, the second cooling water channel being located below the quartz window, the first cooling water channel being connected to a first water inlet and outlet, the second cooling water channel being connected to a second water inlet and outlet, and the first cooling water channel and the second cooling water channel winding the outer side of the microwave cavity and being communicated.

Preferably, the cooling water channel further includes a third water inlet and outlet arranged at the bottom of the microwave cavity, the third water inlet and outlet being communicated with the third cooling water channel below the sample stage.

Preferably, an exhaust hole corresponding to the upper cooling air inlet is formed above the quartz window in the microwave cavity.

Preferably, a cooling air hood and a lower cooling air inlet are arranged above the outer side of the microwave cavity, the lower cooling air inlet being communicated with the exhaust hole.

Preferably, a gas injection opening is arranged below the quartz window in the microwave cavity, and an exhaust vent is arranged in one side of the bottom of the microwave cavity.

Preferably, no less than one observation window is arranged in the surface of the microwave cavity.

Therefore, the structure of the cavity, the sealing structure of the quartz window, heat dissipation and the like of the microwave plasma chemical vapor deposition device disclosed by the present invention are improved, so that the product quality of a diamond film produced by deposition is improved.

The technical solution of the present invention will be further described in detail below in combination with drawings and embodiments.

### BRIEF DESCRIPTION OF THE DRAWINGS

FIG. 1 is a sectional side view of a microwave plasma chemical vapor deposition device.

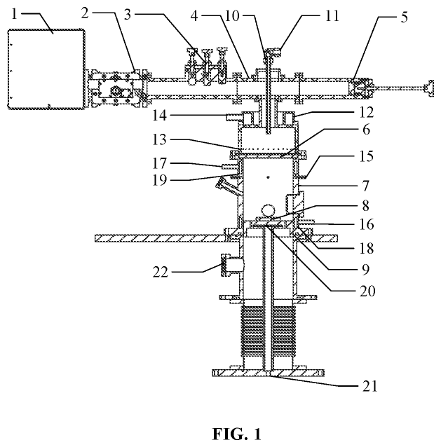

FIG. 2 is a front section view of the microwave plasma chemical vapor deposition device.

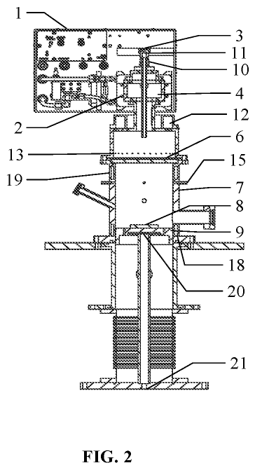

1. microwave generator; 2. isolator; 3. 3-stub microwave tuner; 4. microwave mode converter; 5, short circuiting piston; 6. quartz window; 7. microwave cavity; 8. metal molybdenum stage; 9. sample stage; 10. microwave antenna; 11. upper cooling air inlet; 12. cooling air hood; 13. exhaust hole; 14. lower cooling air inlet; 15. gas injection opening; 16. first water inlet and outlet; 17. second air inlet and outlet; 18. first cooling water channel; 19. second cooling water channel; 20. third cooling water channel; 21. third water inlet and outlet; and 22. exhaust vent.

### DETAILED DESCRIPTION OF THE EMBODIMENTS

The technical solution of the present invention will be further described below in combination with drawings and embodiments.

Unless otherwise defined, the technical terms or scientific terms used herein shall be regarded as ordinary meaning understandable by those of ordinary skill in the art. Terms such as cooling water channel; 19. ske used herein do not mean any sequence, quantity or importance and are only used for differentiating different components. Similar terms such as “comprise” or “include” mean that elements or objects in front of the terms cover elements or objects and equivalent thereof illustrated behind the terms, with other elements or objects included. Similar terms such as “connect” or “connection” are not limited to physical or mechanical connections but can include electric connections, regardless of direct or indirect connections. Terms “upper”, “lower”, “left”, “right” and the like are only used for representing relative position relations. When the absolute positions of the described objects are changed, the relative position relations may be changed correspondingly.

A core component of a microwave plasma chemical vapor deposition device is a resonant cavity for generating microwave plasmas, and the structure of the resonant cavity directly affects distribution and degree of ionization of the plasmas.

As shown in the figures, a microwave plasma chemical vapor deposition device includes a microwave generator 1, an isolator 2, a 3-stub microwave tuner 3, a microwave mode converter 4 and a short-circuiting waveguide tuner 5 connected successively. A quartz window 6 located in the microwave cavity 7 is arranged below the microwave mode converter 4, and a metal molybdenum stage 8 is arranged on a sample stage 9 in the microwave cavity 7.

A microwave tuning and coupling structure is improved: the microwave generator 1 emits a microwave power source which couples microwave energy to the microwave mode converter 4 through the isolator 2, the 3-stub microwave tuner 3 and the short-circuiting waveguide tuner 5, and the microwave energy is coupled to the microwave cavity 7 through the quartz window 6 by means of the microwave antenna 10.

Process gases are injected into the microwave cavity 7 from the gas injection openings 15 distributed in the periphery of the microwave cavity 7, an exhaust vent 22 is arranged in the bottom side of the microwave cavity, and the process gases include CH₄, H₂, CO₂, O₂, N₂, Ar and the like. The microwave energy excites a low pressure gas to generate plasmas above the metal molybdenum stage 8 so as to deposit a diamond film on a seed crystal.

The cooling water channel includes a first cooling water channel 18 arranged below the outer side of the microwave cavity and a second cooling water channel 19 arranged above the outer side of the microwave cavity 7, the second cooling water channel 19 being located below the quartz window 6.

The first cooling water channel 18 is connected to a first water inlet and outlet 16, the second cooling water channel 19 is connected to a second water inlet and outlet 17, and the first cooling water channel 18 and the second cooling water channel 19 wind the outer side of the microwave cavity 7 and are communicated.

Cooling water enters from the first water inlet and outlet 16 and the second water inlet and outlet 17 respectively. Therefore, the cooling water flows in the first cooling water channel 18 and the second cooling water channel 19, so that the cooling efficiency and the flowing sealing performance of the cooling water are improved. After heat exchange, the cooling water is discharged from the first water inlet and outlet 16 and the second water inlet and outlet 17.

The cooling water enters form a third water inlet and outlet 21 and flows in a third cooling water channel 20. After heat exchange, the cooling water is then discharged from the third water inlet and outlet 21.

The cooling water flows among the first water inlet and outlet 16, the second water inlet and outlet 17, the third water inlet and outlet 21, the first cooling water channel 18, the second cooling channel 19 and the third cooling channel 20, indicating that the cooling water can absolutely flow around the microwave cavity 7. Therefore, the cooling effect on the microwave cavity 7 is enhanced.

At least one observation window is arranged outside the microwave cavity 7 for measuring the temperature and observing the state of the plasmas.

A microwave antenna 10 and an upper cooling air inlet 11 stretching into the microwave cavity 7 and corresponding to the upper side of the quartz window 6 are arranged on the microwave mode converter 4, an exhaust hole 13 corresponding to the upper cooling air inlet 11 is arranged above the quartz window 6 in the microwave cavity 7, and the cooling air enters from the microwave antenna 10 and the upper cooling air inlet 11, passes through the quartz window 6 and is finally discharged from the exhaust hole 13.

A cooling air hood 12 and a lower cooling air inlet 14 are arranged above the outer side of the microwave cavity 7, the lower cooling air inlet 14 being communicated with the exhaust hole 13. The cooling air can further enter from the lower cooling air inlet 14, passes through the cooling air hood 12, and is finally discharged from the exhaust hole 13.

The above two solutions improve the cooling structure of the quartz window 6, so that the heat dissipating efficiency of the quartz window 6 is improved.

Therefore, the structure of the cavity, the sealing structure of the quartz window, heat dissipation and the like of the microwave plasma chemical vapor deposition device disclosed by the present invention are improved, so that the product quality of a diamond film produced by deposition is improved.

Finally, it is to be noted that the above embodiments are only used to explain the technical solution of the present invention and shall not be construed as a limitation thereto. Although the present invention is described in detail with reference to preferred embodiments, those of ordinary skill in the art shall understand that they still can modify or equivalently substitute the technical solution of the present invention. These modifications or equivalent substitutions do not deviate the modified technical solution from the spirit and scope of the technical solution of the present invention.

What is claimed is:

1. A microwave plasma chemical vapor deposition device, comprising a microwave generator, an isolator, a 3-stub microwave tuner, a microwave mode converter, and a short-circuiting waveguide tuner connected successively, wherein a microwave antenna and an upper cooling air inlet stretching into a microwave cavity and corresponding to an upper side of a quartz window are arranged on the microwave mode converter, the quartz window located in the microwave cavity is arranged below the microwave mode converter, a metal molybdenum stage is arranged on a sample stage in the microwave cavity, and a cooling water channel is arranged on the microwave cavity.

2. The microwave plasma chemical vapor deposition device according to claim 1, wherein the cooling water channel comprises a first cooling water channel arranged below an outer side of the microwave cavity and a second cooling water channel arranged above the outer side of the microwave cavity, the second cooling water channel is located below the quartz window, the first cooling water channel is connected to a first water inlet and a first water outlet, the second cooling water channel is connected to a second water inlet and a second water outlet, and the first cooling water channel and the second cooling water channel are wound on the outer side of the microwave cavity and communicate to each other.

3. The microwave plasma chemical vapor deposition device according to claim 2, wherein the cooling water channel further comprises a third water inlet and a third water outlet arranged at a bottom of the microwave cavity, wherein the third water inlet and the third water outlet communicate with a third cooling water channel below the sample stage.

4. The microwave plasma chemical vapor deposition device according to claim 1, wherein an exhaust hole corresponding to the upper cooling air inlet is formed above the quartz window in the microwave cavity.

5. The microwave plasma chemical vapor deposition device according to claim 4, wherein a cooling air hood and a lower cooling air inlet are arranged above an outer side of the microwave cavity, and the lower cooling air inlet communicates with the exhaust hole.

6. The microwave plasma chemical vapor deposition device according to claim 1, wherein a gas injection opening is arranged below the quartz window in the microwave cavity, and an exhaust vent is arranged in one side of a bottom of the microwave cavity.

7. The microwave plasma chemical vapor deposition device according to claim 1, wherein no less than one observation window is arranged in a surface of the microwave cavity.
